(19) United States
(12) Patent Application Publication
(10) Pub. No.: US 2024/0184967 A1
(43) Pub. Date: Jun. 6, 2024

(54) FOCUSED TESTING AND VERIFICATION OF CIRCUIT DESIGNS USING HARDWARE DESCRIPTION LANGUAGE SIMULATION

(71) Applicant: Western Digital Technologies, Inc., San Jose, CA (US)

(72) Inventors: Eran Arad, Yuvalim (IL); Efi Dalumi, Atzmon (IL); Yaniv Ne'eman, Gilon (IL); Ori Levi, Kiryat Bialik (IL)

(21) Appl. No.: 18/226,199

(22) Filed: Jul. 25, 2023

Related U.S. Application Data
(60) Provisional application No. 63/430,497, filed on Dec. 6, 2022.

(51) Int. Cl. G06F 30/347; G06F 30/343

(52) U.S. Cl. CPC G06F 30/347; G06F 30/343

(57) ABSTRACT

The disclosure discloses various systems, apparatuses, devices, and methods for verification and testing of hardware description language (HDL) and field-programmable gate array (FPGA) designs. A waveform dump generated in a verification environment or in-FPGA environment can be used to prepare a stimulus file that is configured to reduce the time needed to fix an error/issue found in an HDL/FPGA design. In the verification environment, the stimulus file can reduce the simulation time of an HDL design needed to reproduce the error/issue encountered in a full cycle simulation. Similarly, in the in-FPGA environment, the stimulus file can reduce the simulation time needed to reproduce the error/issue encountered in the FPGA hardware test. In both cases, the techniques for configuring stimulus file can accelerate the process of debugging, testing, and verifying a design using simulation.

### CROSS-REFERENCE TO RELATED APPLICATIONS

This application claims priority to and the benefit of U.S. Provisional Patent Application No. 63/430,497, filed on Dec. 6, 2022 entitled, “FOCUSED TESTING AND VERIFICATION OF CIRCUIT DESIGNS USING HARDWARE DESCRIPTION LANGUAGE SIMULATION,” the entire content of which is incorporated herein by reference as if fully set forth below in its entirety and for all applicable purposes.

### FIELD

The disclosure relates, in some aspects, to circuit designs, and more particular to, focused testing and verification of circuit designs using hardware description language (HDL) simulation.

### Introduction

Electronic systems and devices can be designed and implemented in various ways, for example, using a hardware description language (HDL). Some examples of HDLs include Verilog and Very High Speed Integrated Circuit (VHSIC) Hardware Description Language (VHDL). Both Verilog and VHDL are standardized by the Institute of Electrical and Electronics Engineers (IEEE). An electronic device can contain various circuit components (e.g., digital and/or analog circuitry) to perform specific operations or functions. When an electronic device is designed using HDL and/or implemented using field-programmable gate arrays (FPGA) devices, the design can be verified and tested in an HDL verification environment. Verification of an HDL or FPGA design ensures that the design can perform correctly as designed. If there is any error or issue found during verification, fixes or modification to the design can be made before the design is finalized.

### SUMMARY

The following presents a simplified summary of some aspects of the disclosure to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present various concepts of some aspects of the disclosure in a simplified form as a prelude to the more detailed description that is presented later.

In one embodiment, a method for verifying functionality of a circuit design is provided. The method perform a test of the circuit design to identify a circuit design error within a first duration of the test. The method further generates waveform data for a plurality of signals of the circuit design, the waveform data comprising values of the plurality of signals, generated from the test. The method further generates a stimulus file based on the waveform data, the stimulus file comprising the values of a subset of the plurality of signals and configured to be used to simulate the circuit design to reproduce the circuit design error. The method further performs one or more first simulations of the circuit design using the stimulus file to reproduce the circuit design error, each performed within a second duration shorter than the first duration.

In one embodiment, a computer system for verifying functionality of a circuit design is provided. The computer system includes a processor and a memory operatively coupled to the processor. The processor is configured to perform a test of the circuit design to identify a circuit design error within a first duration of the test. The processor is further configured to generate waveform data for a plurality of signals of the circuit design, the waveform data comprising values of the plurality of signals, generated from the test. The processor is further configured to generate a stimulus file based on the waveform data, the stimulus file comprising the values of a subset of the plurality of signals and configured to be used to simulate the circuit design to reproduce the circuit design error. The processor is further configured to perform one or more first simulations of the circuit design using the stimulus file to reproduce the circuit design error, each performed within a second duration shorter than the first duration.

These and other aspects of the disclosure will become more fully understood upon a review of the detailed description, which follows. Other aspects, features, and implementations of the disclosure will become apparent to those of ordinary skill in the art, upon reviewing the following description of specific implementations of the disclosure in conjunction with the accompanying figures. While features of the disclosure may be discussed relative to certain implementations and figures below, all implementations of the disclosure can include one or more of the advantageous features discussed herein. In other words, while one or more implementations may be discussed as having certain advantageous features, one or more of such features may also be used in accordance with the various implementations of the disclosure discussed herein. In similar fashion, while certain implementations may be discussed below as device, system, or method implementations, it should be understood that such implementations can be implemented in various devices, systems, and methods.

### BRIEF DESCRIPTION OF THE DRAWINGS

A more particular description is included below with reference to specific aspects illustrated in the appended drawings. Understanding that these drawings depict only certain aspects of the disclosure and are not therefore to be considered to be limiting of its scope, the disclosure is described and explained with additional specificity and detail through the use of the accompanying drawings, in which:

FIG. 1 is a block diagram illustrating a computer system that can be configured to perform simulation, testing, and verification of various electronic designs and field-programmable gate arrays (FPGA) designs in accordance with some aspects of the disclosure.

FIG. 2 is block diagram of an exemplary circuit design that illustrates a process for analyzing an error/issue found during verification and/or simulation according to some aspects of the disclosure.

FIG. 3 is a drawing illustrating some exemplary signal waveforms generated by a simulation or testing of a circuit design according to some aspects of the disclosure.

FIG. 4 is a flow chart illustrating a circuit design verification environment process according to some aspects of the disclosure.

FIG. 5 is a table illustrating an exemplary waveform dump of a circuit design according to some aspects of the disclosure.

FIG. 6 is an example of a stimulus file for simulating a circuit design according to some aspects of the disclosure.

FIG. 7 is a block diagram illustrating a computer system that can be configured to perform simulation and testing of a circuit design using FPGA devices in accordance with some aspects of the disclosure.

FIG. 8 is a flow chart illustrating an in-FPGA environment process according to some aspects of the disclosure.

FIG. 9 is a flow chart illustrating an exemplary process of generating verification stimuli according to some aspects of the disclosure.

FIG. 10 is a flow chart illustrating a method of accelerated testing of a circuit design according to some aspects of the disclosure.

### DETAILED DESCRIPTION

In the following detailed description, reference is made to the accompanying drawings, which form a part thereof. In addition to the illustrative aspects, aspects, and features described above, further aspects, aspects, and features will become apparent by reference to the drawings and the following detailed description. The description of elements in each figure may refer to elements of proceeding figures. Like numbers may refer to like elements in the figures, including alternate aspects of like elements.

Designing electronic systems, devices, and apparatuses often involve testing and verification of the designs. An electronic device or system can be realized using hardware description language (HDL) and/or field-programmable gate arrays (FPGA) devices. Some non-limiting examples of such devices and systems include data storage devices and systems, memory devices, magnetic storage devices, data communication devices, interconnecting devices, etc. Some examples of HDLs include Verilog and VHDL which are standardized by the Institute of Electrical and Electronics Engineers (IEEE).

Testing and verifying an HDL design can be complicated and time-consuming. An HDL design (e.g., register transfer level (RTL) design) can be simulated, tested, and verified in a verification environment. The verification environment allows any error or issue of a design to be observed and analyzed so that a solution (e.g., a fix or modification) can be applied to the design. However, after applying a potential correction to the design, it can take a relatively long time to get to the point (e.g., in the simulation) where the error/issue occurred in order to verify that the applied solution would fix the error/issue as expected. Some tests used in a verification environment can run for a long time (e.g., hours or days), and whenever an error is detected, it is analyzed so that a potential solution can be prepared and tested. Then the design with the applied solution is simulated and verified again. This process can be repeated until the error/issue is fixed. This iterative process can take a lot of time because each repeated simulation can take a long time.

Testing and debugging an FPGA design can be performed using in-circuit testing tools (e.g., embedded tools) that can probe, monitor, and sense the various signals or waveforms of an FPGA during testing. For example, a logic analyzer can be embedded (e.g. in-FPGA) in a certain FPGA device used to implement an electronic circuit design. Testing and debugging an FPGA device using in-FPGA tools (e.g., logic analyzer) can be called an in-FPGA environment in this disclosure. In the in-FPGA environment, after an error/issue is found using an in-FPGA testing tool, a potential solution can be made to the design and tested in an FPGA device. The testing of the potential solution can take a time-consuming cycle of FPGA synthesis, implementation, and testing before the solution can be confirmed to work as expected. In some aspects, the in-FPGA testing tool can monitor, acquire, and output signal waveform data (waveform dump) from the FPGA device while the design is synthesized and tested in FPGA hardware. Whenever an error/issue is found, the waveform dump can be analyzed to determine the possible cause of the error in order to prepare a potential solution.

The disclosure relates in some aspects to various systems, apparatuses, devices, and methods for verification and testing of HDL and FPGA designs. In some aspects, a waveform dump generated in a verification environment or in-FPGA environment can be used to prepare a stimulus file that is configured to reduce the time needed to fix an error/issue found in an HDL/FPGA design. In the verification environment, the stimulus file (e.g., System Verilog test case) can reduce the simulation time of an HDL design needed to reproduce the error/issue encountered in a full cycle simulation. Similarly, in the in-FPGA environment, the stimulus file can reduce the simulation time needed to reproduce the error/issue encountered in the FPGA hardware test. In both cases, the techniques for configuring stimulus file can accelerate the process of debugging, testing, and verifying a design using simulation.

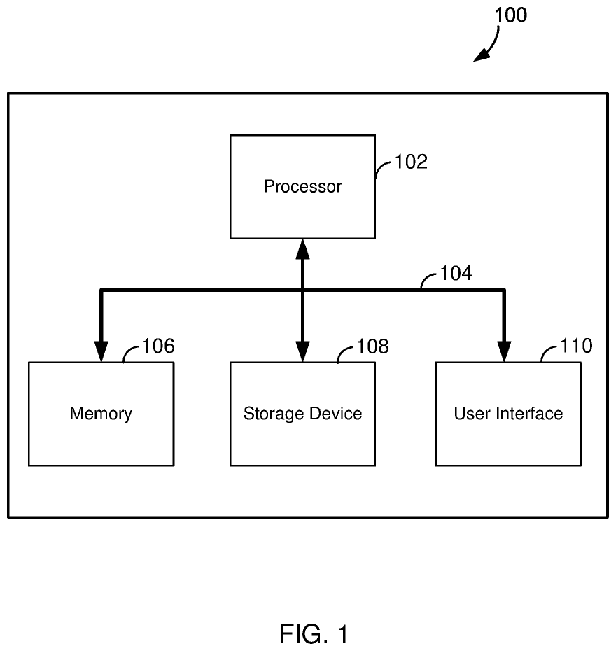

FIG. 1 is a block diagram illustrating a computer system 100 that can be configured to perform various functions and processes used for designing and verifying electronic devices and FPGA devices in accordance with some aspects. In some aspects, the computer system 100 can include one or more processors (e.g., an exemplary processor 102 shown in FIG. 1). The processor 102 can be implemented using a general or special purpose processor such as, for example, a microprocessor, controller, microcontroller, or other processing devices. The processor 102 can communicate with other components of the computer system 100 via a communication medium 104 (e.g., a bus, universal series bus (USB), peripheral component interconnect express (PCIe) connection, etc.). The computer system 100 further includes a main memory 106, for example, random access memory (RAM) or the like, for storing information and instructions that can be used and executed during the execution of software that can provide a verification environment or in-FPGA environment. The computer system 100 can include a persistent computer-readable storage (e.g., persistent storage device 108) that may include, for example, a hard disk drive, an optical disk drive, a solid state drive (SSD), and/or a fixed media drive. In some aspects, the computer system 100 can include a read-only memory (“ROM”) or other static storage devices (e.g., NAND) for storing static information, data, and instructions. In some aspects, the main memory 106 and/or the storage device 108 may store data such as signal waveform data, stimulus files, and/or computer programs (e.g., System Verilog and/or VHDL design software, etc.) for processes configured for design, simulation, and verification of electronic device and FPGA designs.

In some aspects, the computer system 100 can include a user interface 110 that can be used to display information, for example, information related to verification, testing, and simulation operations and results. In some examples, the user interface 110 can include a display and an input device (e.g., a keyboard, a mouse, a touch screen, a touchpad, etc.).

In this disclosure, the terms “computer program storage medium” and “computer readable medium” may be used to generally refer to media such as, for example, memory 106 and storage devices 108. These and other various forms of computer useable media may be involved in carrying out one or more sequences of one or more instructions at the processor 102 for execution. Such instructions, generally referred to as “computer program code,” “computer instructions.” or “computer executable code.” when executed, enable the computer system 100 to perform the features, functions, and processes of the present disclosure as discussed herein. In some aspects, the computer system 100 can be configured to run HDL (e.g., System Verilog, VHDL) or FPGA simulations of circuit designs. In some aspects, the computer system 100 can be configured to run FPGA design and synthesis software.

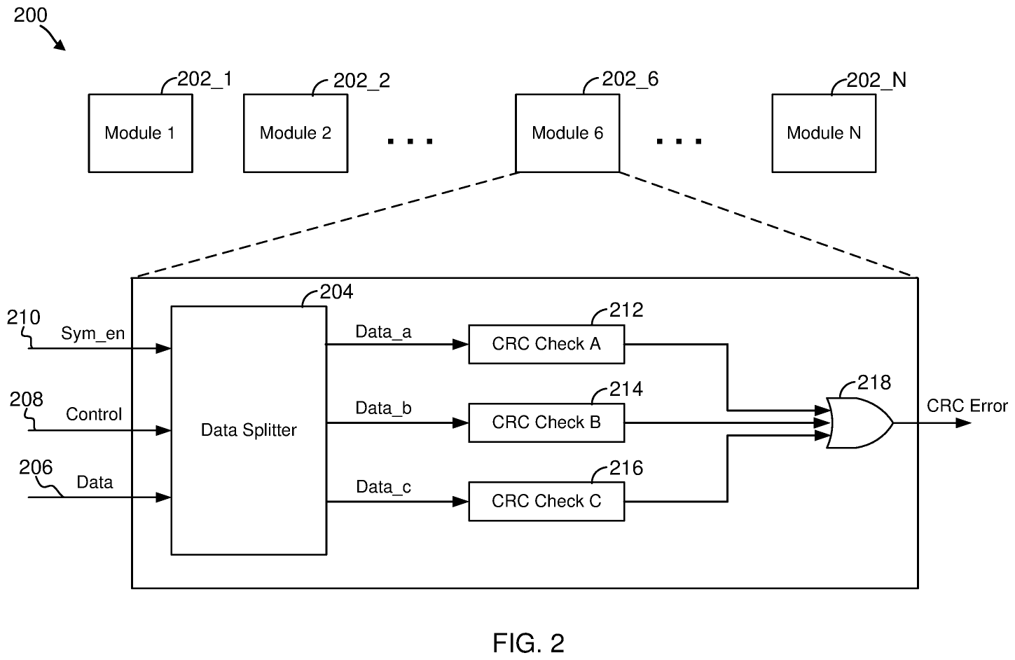

FIG. 2 is a block diagram of an exemplary circuit design 200 for illustrating a process of analyzing an error/issue found during verification and/or simulation. In one example, the circuit design 200 includes a plurality of modules 202_1 to 202_N (e.g., module 1, module 2, . . . , and module N), including modules 202_2 and 202_6. Each of the modules can implement a certain RTL design. For example, module 202_6 (module 6) includes a data splitter 204 that receives a stream of interleaved data inputs 206 that can include different types of data. The data splitter 204 further receives control inputs 208 (e.g., rx_control [15:0]), and enable inputs 210 (e.g., rx_sym_en [15:0]). In this example, the data splitter 204 splits the input data stream 206 (e.g., rx_data [255:0]) into three different data types (Data_a, Data_b, and Data_c), and the data splitter provides the different data types to three different cyclic redundancy check (CRC) checkers 212, 214, and 216. Each CRC checker provides a CRC error indication to a logic gate 218 (e.g., OR gate). Then, the logic gate 218 generates a combined CRC error output to indicate the occurrence of a CRC error of the data stream 206.

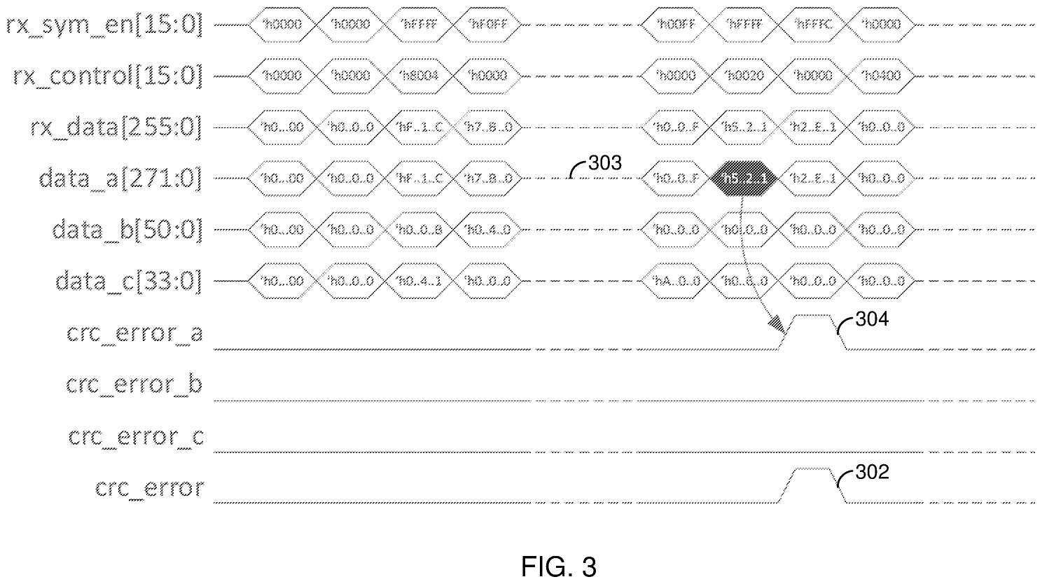

FIG. 3 illustrates some exemplary signal waveforms generated by a simulation or testing of the circuit design 200. In FIG. 3, an occurrence of a CRC error (e.g., CRC error 302) can be an indication of an actual error in the rx_data [225:0] or a design issue in the data splitter 204 that feeds one or more of the CRC checkers 212, 214, and 216 with corrupted data. In this example, the input to the circuit design 200 contains valid data, but data_a [271:0] 303 is corrupted (e.g., contains one or more errors). Therefore, the waveform for the output of CRC checker 212 (cre_error_a which is the output for CRC checker A for data_a) shows a CRC error 304. In some cases, this issue of data_a corruption can occur due to a certain combination and/or sequence of the data inputs and may appear after a long simulation or in a hardware implementation (e.g., FPGA) of the circuit design.

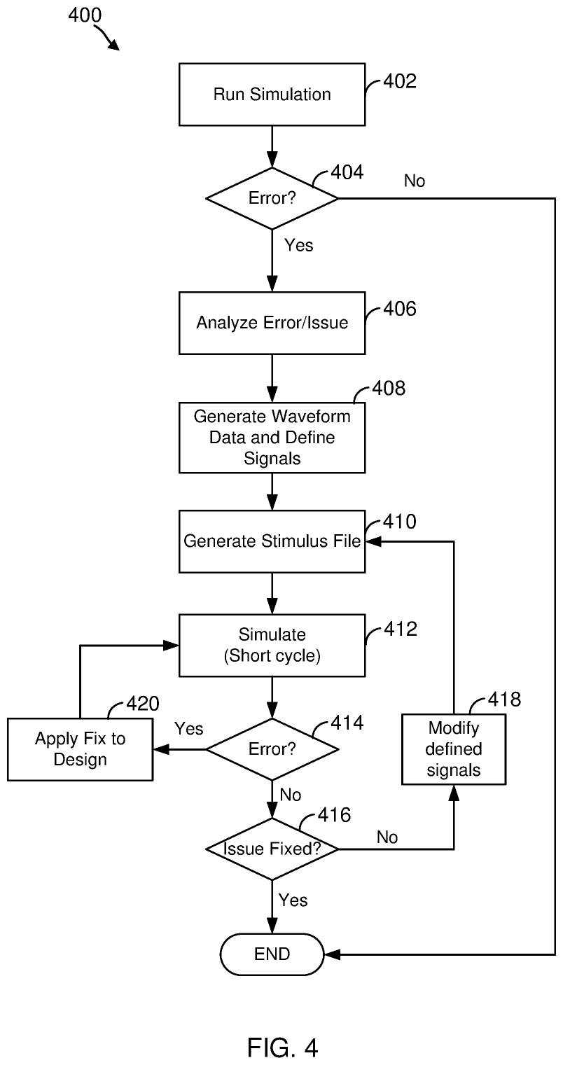

FIG. 4 is a flow chart illustrating a circuit design verification environment process 400 according to some aspects of the disclosure. The verification environment process 400 can accelerate the process for fixing the error/issue of the circuit design 200 described above in relation to FIGS. 2 and 3. In some aspects, the verification environment process 400 can be performed using the computer system 100 or any suitable apparatus configured to perform simulation and testing of an electronic circuit design (e.g., RTL design in HDL). In some aspects, an RTL design can implement an electronic device used in, for example, a storage system, a memory storage, an SSD, a hard disk drive, a memory device, etc. In some aspects, the computer system 100 can be a means to perform the verification environment process described below.

At 402, the process runs a simulation to verify the circuit design 200. In one example, the process performs a test (e.g., simulation) that can be prepared using HDL (e.g., System Verilog or VHDL). The simulation can use various stimuli to drive or test the circuit design 200 during the simulation. The response (e.g., output signals) of the circuit design can be monitored and observed in response to the stimuli. In one example, a test engineer can configure and use the computer system 100 of FIG. 1 to run the simulation or test of the circuit design 200.

At 404, if the process determines that no error or issue occurred in the simulation, the verification of the circuit design 200 can be completed. In one example, the test engineer and/or the computer system 100 (FIG. 1) running the process can determine whether or not an error occurred in the simulation. At 406, if the process determines that an error occurred, the simulation result of the circuit design 200 can be analyzed to determine the possible cause of the error/issue observed. In one example, the test engineer and/or the computer system 100 of FIG. 1 can analyze the error to determine the possible cause of the error/issue observed.

At 408, the computer system 100 running the simulation can generate a waveform dump (e.g., collect aggregated waveform data of selected signals) of the circuit design based on the simulation. In some aspects, the process can create a file that contains the values of the selected signals or waveforms of the design circuit 200 generated during the simulation. In one example, the process may generate the waveform dump in a preselected format such as a Verilog value changed dump (VCD). In other examples, the waveform dump may be generated in other suitable formats, e.g., comma-separated values (CSV), etc. In one example, the test engineer can operate the computer system 100 of FIG. 1 to generate the waveform dump.

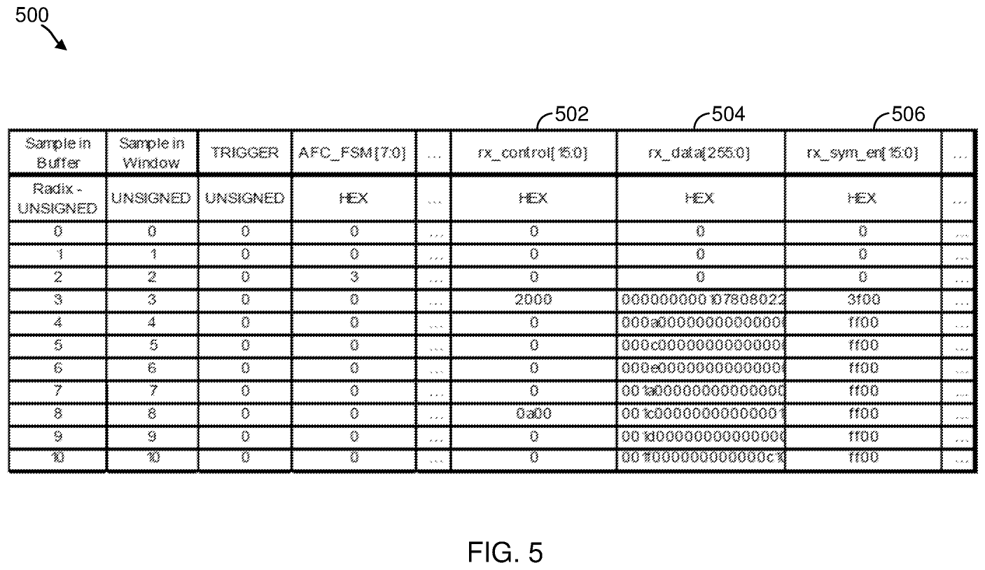

FIG. 5 illustrates a portion of an exemplary waveform dump 500 of the circuit design 200 generated from the simulation at 402 of FIG. 4. In one example, the waveform dump 500 may be in a CSV format (shown in FIG. 5) or VCD format. Each row (of numbers) in the waveform dump 500 can correspond to one clock cycle or trigger. In this example, the waveform dump includes the values of control signal 502 (rx_control [15:0]), data signals 504 (rx_data [255:0]), and enable signals 506 (rx_system_en [15:0]) at different points in time (e.g., time points 0-11 shown in FIG. 5) during the simulation.

Returning now to FIG. 4 and based on the issue/error identified at 404 and/or 406, one or more signals/waveforms of the circuit design 200 can be defined or selected in order to generate a stimulus file (e.g., stimuli) for reproducing the error/issue in a shorter or faster simulation. For example, the relevant signals may include the data inputs 504, control inputs 502, and enable inputs 506. At 410, the computer system 100 (e.g., processor 102) can generate the stimulus file (e.g., stimuli) from the waveform dump and selected signals. The stimulus file and selected signals are configured to reproduce the issue/error in a targeted/focused simulation faster than a full cycle simulation that involves all of the signals of the circuit design. In some aspects, the stimulus file may be an RTL verification stimulus file. In one example, the test engineer can operate the computer system 100 of FIG. 1 to generate the stimulus file.

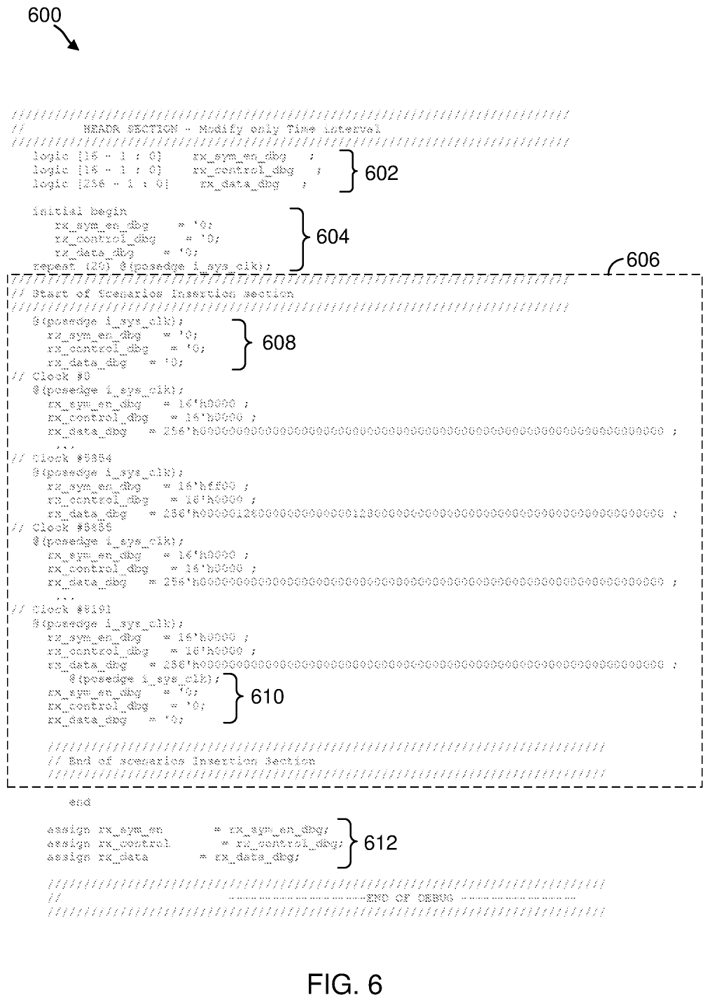

FIG. 6 is a drawing conceptually illustrating an exemplary stimulus file 600 according to some aspects of the disclosure. In one example, the stimulus file 600 may be an RTL verification stimulus file (e.g., System Verilog stimuli code). The stimulus file 600 has a first section 602 that lists/defines a subset of the signals/waveforms of the DUT, including for example, enable inputs 506 (rx_sym_en_dbg), control inputs 502 (rx_control_dbg), and data inputs 504 (rx_data_dbg). These selected signals (debug signals) can be initialized to a predetermined value (e.g., a value of 0). A second section 604 of the stimulus file can initialize the selected signals. For example, rx_sym_en_dbg, rx_control_dbg, and rx_data_dbg can each be initialized to a value of 0.

The stimulus file 600 further includes an insertion section 606 that defines a plurality of scenarios to be simulated in a temporal order, for example, using the computer 100. In each scenario, the clock signal (e.g., i_sys_elk) and selected signals (e.g., rx_sym_en_dbg, rx_control_dbg, and rx_data_dbg) can be set to the corresponding values selected from the waveform dump. Some exemplary simulation scenarios (Clock #0, #5854, #5855, and #8191) are shown in FIG. 6. At 608, the simulation waits for the rising edge of the clock and sets the debug signals to their initial values (e.g., a value of 0). For example, in a first scenario (Clock #0), the simulation waits for the rising edge of the clock and sets the debug signals to the corresponding values (e.g., 16 h, 16 h, 256 h) selected from the waveform dump for Clock #0. At 610, after simulating the scenarios (Clock #0 to Clock #8191), the simulation waits for the rising edge of the clock and sets the debug signals to the predetermined final values (e.g., a value of 0). Then, at 612, the stimulus file assigns the output signals (e.g., rx_sym_en, rx_control, rx_data) to the value of the debug signals (rx_sym_en_dbg, rx_control_dbg, rx_data_dbg).

At 412, referring back to FIG. 4, the process can simulate the circuit design 200 using the stimulus file generated at 410. In one example, the test engineer can operate the computer system 100 of FIG. 1 to simulate the circuit design 200 using the stimulus file. Because the stimulus file include a subset of all signals and/or waveforms of the circuit design, the simulation of the circuit design using the stimulus file can reproduce the error/issue faster than the full cycle simulation at 402 that uses all of the signals. That is, the stimulus file is configured (by having fewer signals than those included in the full simulation) to accelerate the reproduction of the error/issue found in the full simulation. In some examples, the stimulus file can be used to simulate the design, or a portion of the design, in a time window during which the error occurred, and the time window can start at a time point that is later than the starting time of the full simulation at 402. In one example, the short cycle simulation at 412 can start at a time point closer to the occurrence of the error than the starting time of the full simulation. Further, when the stimulus file includes only a subset of all signals/waveforms of the circuit design, the simulation can run faster than a full cycle simulation that includes all of the signals.

At 414, after running the short cycle simulation, the process checks whether or not the stimulus file reproduced the error/issue that occurred in the long cycle simulation. In one example, the test engineer can operate the computer system 100 of FIG. 1 to check the result of the short cycle simulation. At 416, if no error/issue was reproduced, the process checks whether or not the error/issue has been fixed. The error/issue is not fixed yet if no error/issue is found after running the short cycle simulation only once. This is because no changes have been made to the design at this point. In one example, the test engineer can operate the computer system 100 of FIG. 1 to check whether or not the error/issue has been fixed.

At 418, after determining that the issue was not fixed, the process modifies the defined signals or waveforms, for example, by adding more signals that can be relevant to the error/issue found in the long simulation. In one example, the test engineer can operate the computer system 100 of FIG. 1 to modify the defined signals or waveforms. Then, at 410, the process generates the stimulus file again based on the modified defined signals. Then, at 412, the process simulates the circuit design again with the new stimulus file and checks for the occurrence of the error/issue at 414.

At 420, if an error/issue is reproduced after the short cycle simulation at 412, the process can apply a potential solution the circuit design. For example, the solution can be designed by an engineer based on the analysis of the error found earlier during the full cycle simulation, for example, using the waveform data generated by the full cycle simulation. In one example, the test engineer can operate the computer system 100 of FIG. 1 to apply the fix to the circuit design. At 412, the process simulates the circuit design again with the solution applied and checks for the error/issue again at 414. If the error/issue still occurs, the above-described procedures can be repeated until an effective solution is found that removes the error/issue.

In various use cases predating this disclosure, the actions of blocks 408 to 418 might simply be replaced with efforts, possibly repeated, by a test engineer to fix the issue and one or more long cycle simulations. As compared to those use cases, process 400 can perform more focused or targeted short simulations that take less time overall.

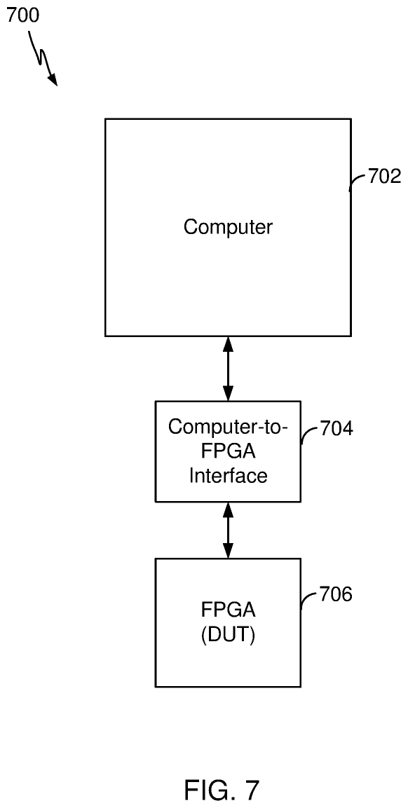

FIG. 7 is a block diagram illustrating an exemplary system 700 that can be configured to perform simulation and testing of a circuit design using FPGA devices in accordance with some aspects. The system 700 includes a computer 702 and a computer-to-FPGA interface 704 for communicating with an FPGA device 706 under test (DUT). In some aspects, the computer-to-FPGA interface 704 can be included as a part of the computer 702. In one example, the computer 702 may be the computer system 100 of FIG. 1 or any suitable computer that can be configured with software and/or hardware for designing, synthesizing, downloading, testing, and/or simulating FPGA designs. In some aspects, the computer system 700 can provide an in-FPGA environment for testing and verifying FPGA designs.

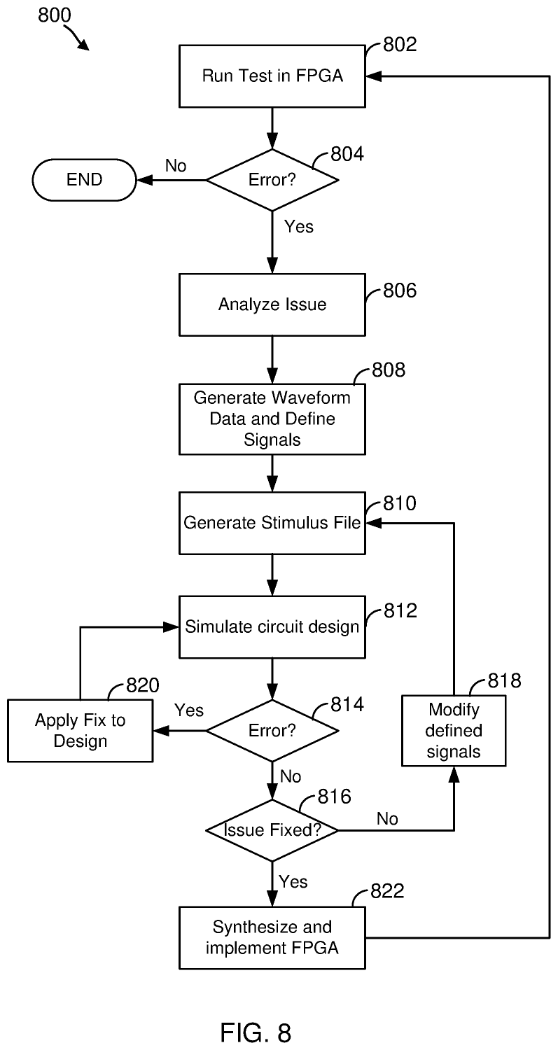

FIG. 8 is a flow chart illustrating an in-FPGA environment process 800 according to some aspects of the disclosure. The in-FPGA environment process 800 can be implemented using the computer system 700 to test and simulate a circuit design using in-FPGA tools (e.g., embedded logic analyzer). In some aspects, a circuit design can be implemented in an FPGA device used in, for example, a storage system, a memory storage, an SSD, a hard disk drive, a memory device, etc.

At 802, the process can implement and test a circuit design in an FPGA device to verify the design (e.g., circuit design 200 of FIG. 2). In one example, an engineer can use the computer 702 of FIG. 7 to prepare the circuit design using HDL tools (e.g., Verilog, VHDL, etc.). In one example, an engineer can use the computer 702 of FIG. 7 to capture, synthesize, and implement the circuit design 200 (see FIG. 2) using a specific or preselected FPGA device 706. Then, the computer 702 can download the circuit design into the FPGA 706 via the computer-to-FPGA interface 704. The process can test the circuit design downloaded into the FPGA 706 using different stimuli (e.g., vectors or inputs) to verify the circuit design. During the test, the process can monitor and gather the output signals, waveforms, and/or responses of the FPGA using in-FPGA tools, including for example, a logic analyzer. The process can run multiple tests on the FPGA 706 to verify the proper functions of the circuit design. For example, the computer 702 can access the in-FPGA tools via the computer-to-FPGA interface 704.

At 804, if the process determines that no error/issue is observed in the FPGA test, the testing of the circuit design can be completed. Otherwise, at 806, if the process determines that an error/issue occurred, the error/issue can be analyzed to determine the cause of the error/issue observed. For example, a test engineer can use an in-FPGA logic analyzer to probe various waveforms, signals, nodes, inputs, outputs, and/or signal paths of the FPGA 706 during testing to trace and determine the possible cause of the error/issue.

At 808, the computer 702 can generate a waveform dump (e.g., waveform data of predetermined signals or waveforms of the FPGA 706 gathered during testing) that may be relevant to the error/issue. During the FPGA test, the computer 702 can store various signals and waveform data of the FPGA acquired during the test. For example, the computer 702 can generate a waveform dump that contains the values of selected signals of the FPGA that may be relevant or helpful for debugging the error/issue. For example, the process can generate the waveform dump in a preselected format such as Verilog VCD format, CSV format, or any format suitable for generating a stimulus file (e.g., stimuli) capable of reproducing the error/issue of the circuit design. In some examples, the waveform dump may be similar to the waveform dump 500 described above in conjunction with FIG. 5. Based on the analysis of the issue/error, the process can select one or more signals of the circuit design to generate a stimulus file (e.g., stimuli) for an accelerated simulation of the circuit design to reproduce the issue/error. In one example, the waveform dump (e.g., waveform dump 500 of FIG. 5) includes the values of control signal 502 (rx_control [15:0]), input data 504 (rx_data [255:0]), and system enable signals 506 (rx_system_en [15:0]) gathered at different times during the FPGA test using in-FPGA tools (e.g., logic analyzer).

At 810, the computer 702 can generate the stimulus file from the waveform dump and defined signals. The stimulus file is configured to reproduce the error/issue in a simulation to enable debugging and subsequent preparation of a solution for the error/issue before implementing the solution in hardware (e.g., FPGA). In some aspects, the stimulus file may be an RTL verification stimulus file (e.g., an RTL verification stimulus file 600) according to some aspects of the disclosure. For example, the stimulus file 600 can define one or more signals, for example, enable inputs 210 (rx_sym_en_dbg), control inputs 208 (rx_control_dbg), and data inputs 206 (rx_data_dbg) of the circuit design 200 to be simulated.

At 812, the computer 702 can be configured to simulate the circuit design using the stimulus file generated at 810. The stimulus file can include a subset of all of the signals and/or waveforms of the circuit design that can be implemented in the FPGA. Using the stimulus file to simulate and reproduce the error/issue allows a fix or modification to be made and tested quickly instead of testing the fix/modification in actual FPGA hardware. Without this quick simulation using the stimulus file, testing the potential solution in FPGA hardware needs to go through time-consuming processes including FPGA synthesis, implementation, and downloading. In some scenarios, multiple FPGA synthesis cycles (e.g., which are time-consuming) may be needed to determine and verify a solution for the error/issue of the circuit design. In some examples, the stimulus file can be configured to be used for simulation of the circuit design within a specific time window during which the error/issue occurred, during the FPGA test. The time window can start at a time point later than the starting time of a full simulation of the circuit design using the waveform dump. For example, the shorter simulation can start at a time point close to (e.g., shortly before) the time when the error/issue occurred. Because the stimulus file includes only a subset of all signals/waveforms of the waveform dump gathered from the FPGA test, the simulation can be completed in a shorter time (e.g., substantially shorter time) than the time required for the full simulation of the circuit design or testing in an FPGA device.

At 814, after running the simulation at 812 with the stimulus file, the process checks whether or not the stimulus file reproduced the error/issue. For example, a testing engineer can operate the computer 702 of FIG. 7 to check the simulation result. At 816, if no error/issue occurred, the process checks whether or not the error/issue has been fixed. The error/issue is not fixed yet if no error/issue is found after running the short cycle simulation at 812 only once. This is because no changes have been made to the design at this point. In one example, the test engineer can operate the computer 702 of FIG. 7 to check whether or not the error/issue has been fixed.

At 818, the process modifies the defined signals, for example, by adding more signals and/or using different signals that may be relevant to the error/issue found in the circuit design tested in the FPGA 706. In one example, the test engineer can operate the computer 700 of FIG. 7 to modify the defined signals or waveforms. Then, back at 810, the process generates the stimulus file (e.g., modified stimulus file) based on the modified defined signals. Then, at 812, the process simulates the circuit design again with the modified stimulus file and checks for the error/issue at 814.

At 820, if the error/issue is reproduced after the simulation (e.g., short cycle simulation), the process can apply a potential solution to the circuit design. For example, the solution can be designed by an engineer based on the analysis of the error/issue found earlier during the test running in FPGA hardware. At 812, after applying the solution, the process simulates the circuit design again, but this time with the solution applied, and checks for the error/issue at 814 again. For example, the engineer can operate the computer 702 of FIG. 7 to simulate the circuit design again. If the error/issue still occurs, the above-described procedures can be repeated until an effective solution is found that fixes or removes the error/issue. At 822, when the fix for the error/issue is confirmed in a simulation at 812, the process can synthesize and implement the circuit design in hardware (e.g., FPGA) for testing at 802. If no issue/error is found in the FPGA test, the in-FPGA environment process 800 is completed.

In various use cases predating this disclosure, the actions of blocks 808 to 818 might simply be replaced with efforts, possibly repeated, by a test engineer to fix the issue and one or more long cycle simulations. As compared to those use cases, process 800 can perform more focused or targeted short simulations that take less time overall.

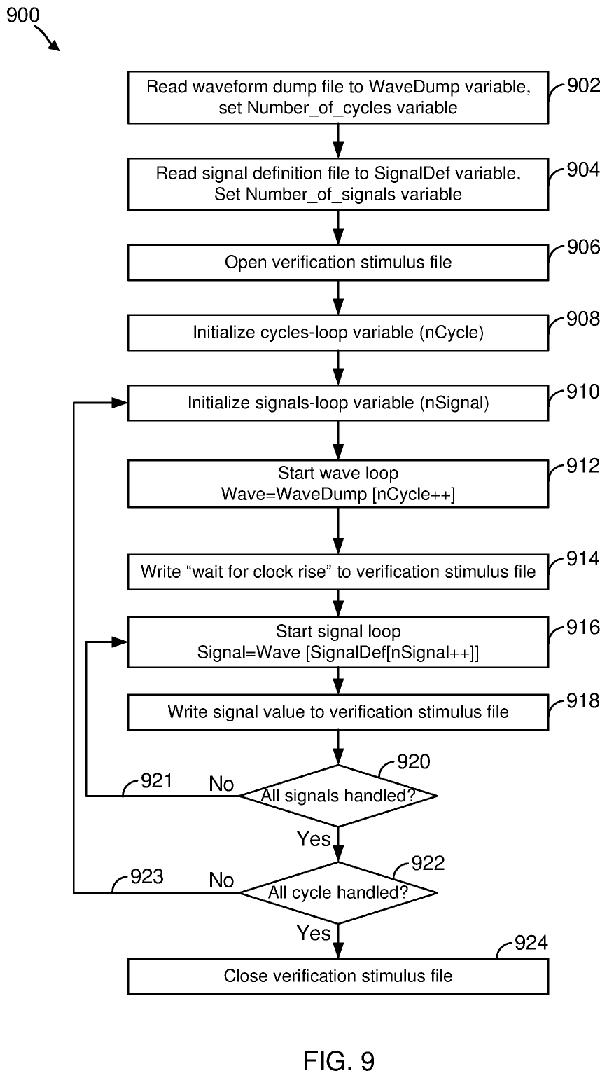

FIG. 9 is a flow chart illustrating a process 900 for generating stimuli according to some aspects of the disclosure. In one aspect, the process 900 can be implemented as software running at the computer system 100 to generate the stimulus file used in the verification environment process 400 described above. In one aspect, the process 900 can be implemented as software running at the computer 702 to generate the stimulus file used in the in-FPGA environment process 800 described above.

At 902, the process can read or import a waveform dump file into a waveform dump variable (e.g., WaveDump). In some aspects, the WaveDump variable can be a database or a data array that can store the values of various waveforms/signals contained in the waveform dump file. For example, the waveform dump file may be the waveform dump 500 of FIG. 5 described above that can be used in the verification environment process 400 and in-FPGA environment process 800. Then, the process can set a number-of-cycles variable (e.g., NumOfCycles) such that it has a value set to equal the number of different signals/waveforms defined in the WaveDump variable.

At 904, the process reads or imports a signal definition file to a SignalDef variable. The signal definition file can contain one or more signals (or waveforms) that may be relevant to the issue/error found in the verification environment process 400 or in-FPGA environment process 800 described above. In some aspects, the SignalDef variable can be a database or a data array that can store one or more signal values. Then, the process sets up a number-of-signals variable (e.g., NumOfSignals) that indicates the number of signals stored in the SignalDef variable.

At 906, the process opens or creates a verification stimulus file for writing. For example, the verification stimulus file can be used for the stimulus file used in the verification environment process and in-FPGA environment process 800 described above. In some aspects, the verification stimulus file can be created and stored on a computer (e.g., computer system 100 or computer 702). In one example, the verification stimulus file may be an RTL verification stimulus file that can be used for the simulations in the verification environment process and in-FPGA environment process 800.

At 908, the process initializes a cycles-loop variable (e.g., nCycle). For example, the process can initialize nCycle to a value of 0 (nCycle=0). At 910, the process initializes a signals-loop variable (e.g., nSignal). For example, the process can initialize nSignal to a value of 0 (nSignal=0) or a predetermined number.

At 912, the process starts a wave loop and sets a wave variable (e.g., Wave) to the appropriate wave stored in the WaveDump variable using nCycle as an index, for example, Wave=WaveDump [nCycle++]. The variable nCycle is incremented after each iteration of the wave loop.

At 914, the process writes “(@ (posedge i_sys_clk)” to the verification stimulus file. This operator “@(posedge i_sys_clk)” causes the simulation to wait for a clock rise and perform the corresponding actions. For example, at 608 of FIG. 6, the simulation waits for the rising edge of the clock and sets the debug signals (rx_sym_en_dbg, rx_control_dbg, and rx_data_dbg) to their initial values (e.g., a value of 0).

At 916, the process starts a signal loop, and sets a signal variable (e.g., Signal) to the appropriate signal from the Wave variable using SignalDef and nSignal as an index, for example, Signal=Wave [SignalDef [nSignal++]]. The index nSignal is incremented after each iteration of the signal loop.

At 918, the process writes the signal value (from Wave variable) to the verification stimulus file (e.g., RTL verification stimulus file 600 of FIG. 6) for the signal currently identified by the Signal variable. At 920, if not all of the signals were handled (i.e., check nSignal), the process continues the signal loop 921. Otherwise, the process continues to decision block 922.

At 922, the process checks if all cycles were handled. At 923, if not all cycles were handled (i.e., check nCycle), the process goes back to 910 and repeats the wave loop. Otherwise, the process can close the verification stimulus file and finish.

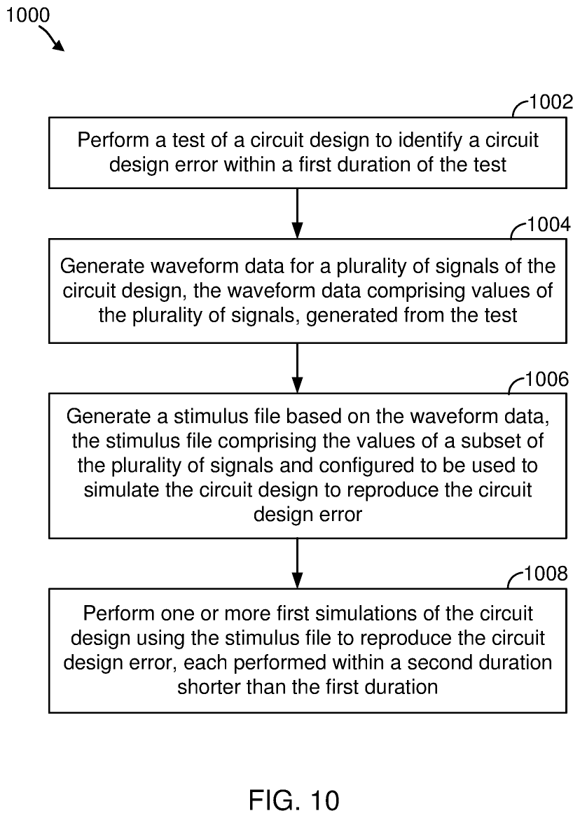

FIG. 10 is a flow chart illustrating a method 1000 for accelerating the testing of a circuit design according to some aspects of the disclosure. In one example, the method 1000 can be used to verify an HDL simulation of the circuit design 200. In one example, the method 1000 can be used to test an FPGA implementation of the circuit design 200. In other aspects, the method 1000 can be used to accelerate the testing and/or verification of electronic devices using simulation and/or initial FPGA testing as described above in relation to FIGS. 1-9. The computer system 100 or computer 702 may provide a means to perform the method 1000.

At 1002, the process performs a test of a circuit design to identify a circuit design error or issue within a first duration of the test. In one example, the circuit design may be an HDL design of the circuit design 200. The HDL design may be a Verilog design or an VHDL design. In one example, testing the circuit design may start with a full simulation (e.g., simulation 402 of FIG. 4) of the electronic circuit design. A full simulation may include simulating all the available signals of the circuit design. In one example, testing the circuit design may include testing the circuit design in an FPGA implementation (e.g., test in an FPGA at 802 of FIG. 8).

At 1004, the process generates waveform data for a plurality of signals of the circuit design. The waveform data can include values of a plurality of signals (or waveforms) of the circuit design generated from the test. For example, the waveform data may be a waveform dump (e.g., Verilog VCD. CSV, etc.) generated in a verification environment process 400 or an in-FPGA environment process 800 as described herein. The waveform dump can contain the values of selected signals or waveforms of the circuit design during testing.

At 1006, the process generates a stimulus file based on the waveform data. For example, the computer 100 of FIG. 1 or computer 702 of FIG. 7 can generate the stimulus file (e.g., stimulus file 600 of FIG. 6). The stimulus file includes the values of a subset of the plurality of signals. The stimulus file is configured to be used for simulating the circuit design to reproduce the circuit design error.

At 1008, the process performs one or more first simulations of the circuit design using the stimulus file to reproduce the circuit design error, each performed within a second duration shorter than the first duration. For example, the computer 100 of FIG. 1 or computer 702 of FIG. 7 can perform the first simulation(s) of the circuit design (e.g., circuit design 200 of FIG. 2) using the stimulus file.

The stimulus file is configured to shorten the simulation time needed to reproduce the circuit design error as compared to the test (e.g., full simulation or FPGA hardware test) to facilitate faster troubleshooting of the circuit design error. In one example, the process can simulate the circuit design one or more times using the stimulus file to reproduce the error in order to prepare a fix for the circuit design error. When a simulation does not reproduce the circuit design error, the stimulus file can be modified until it reproduces the circuit design error.

In one example, the circuit design can be implemented in HDL. Performing the test may include simulating the circuit design in a second simulation, wherein each of the one or more first simulations has a shorter duration than a duration of the second simulation. In one example, performing the test may include: synthesizing the circuit design to be implemented in a FPGA device: testing the synthesized circuit design in the FPGA device: and obtaining the values of the plurality of signals of the circuit design using a logic analyzer provided in the FPGA device. In one example, the stimulus file may include an RTL verification stimulus of the circuit design. In one example, performing one or more first simulations of the circuit design using the stimulus file may include: determining whether or not the one or more first simulations reproduce the circuit design error using the stimulus file: and modifying the subset of the plurality of signals included in the stimulus file in response to determining that the one or more first simulations do not reproduce the circuit design error using the stimulus file. In one example, modifying the subset of the plurality of signals includes at least one of: adding one or more signals to the subset of plurality of signals: or removing one or more signals from the subset of plurality of signals. In one example, generating the waveform data may include generating a value changed dump comprising the values of the plurality of signals. In one example, the stimulus file may include: a first section defining the subset of the plurality of signals; and a second section defining the values of the subset of the plurality of signals in a temporal order for simulating the circuit design in the one or more first simulations. In one example, the method 1000 may modify the circuit design to correct the circuit design error based on the one or more first simulations.

The terms “above.” “below.” “on,” and “between” as used herein refer to a relative position of one layer with respect to other lavers. As such, one layer deposited or disposed on, above, or below another layer may be directly in contact with the other layer or may have one or more intervening layers. Moreover, one layer deposited or disposed between layers may be directly in contact with the layers or may have one or more intervening layers.

In one aspect, the process can perform the sequence of actions in a different order. In another aspect, the process can skip one or more of the actions. In other aspects, one or more of the actions are performed simultaneously. In some aspects, additional actions can be performed.

The foregoing description and drawings of exemplary embodiments are merely illustrative of the principles of the present disclosure. It will be appreciated that the principles of the disclosure can work with a wide variety of different syntax languages such as Verilog, and VHDL languages. Moreover, it is scalable and extensible to support other HDLs like, System Verilog, VerilogA, and SystemC, for example. Therefore, it will be understood that various modifications can be made to the embodiments by those skilled in the art without departing from the spirit and scope of the invention, which is defined in the appended claims.

### Additional Aspects

The examples set forth herein are provided to illustrate certain concepts of the disclosure. The apparatuses, devices, or components illustrated above may be configured to perform one or more of the methods, features, or steps described herein. Those of ordinary skill in the art will comprehend that these are merely illustrative in nature, and other examples may fall within the scope of the disclosure and the appended claims. Based on the teachings herein those skilled in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to or other than one or more of the aspects set forth herein.

Aspects of the present disclosure have been described above with reference to schematic flowchart diagrams and/or schematic block diagrams of methods, apparatuses, systems, and computer program products according to aspects of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

The subject matter described herein may be implemented in hardware, software, firmware, or any combination thereof. As such, the terms “function,” “module,” and the like as used herein may refer to hardware, which may also include software and/or firmware components, for implementing the feature being described. In one example implementation, the subject matter described herein may be implemented using a computer readable medium having stored thereon computer executable instructions that when executed by a computer (e.g., a processor) control the computer to perform the functionality described herein. Examples of computer-readable media suitable for implementing the subject matter described herein include non-transitory computer-readable media, such as disk memory devices, chip memory devices, programmable logic devices, and application specific integrated circuits. In addition, a computer readable medium that implements the subject matter described herein may be located on a single device or computing platform or may be distributed across multiple devices or computing platforms.

It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures. Although various arrow types and line types may be employed in the flowchart and/or block diagrams, they are understood not to limit the scope of the corresponding aspects. For instance, an arrow may indicate a waiting or monitoring period of unspecified duration between enumerated steps of the depicted aspect.

The various features and processes described above may be used independently of one another, or may be combined in various ways. All possible combinations and sub-combinations are intended to fall within the scope of this disclosure. In addition, certain method, event, state or process blocks may be omitted in some implementations. The methods and processes described herein are also not limited to any particular sequence, and the blocks or states relating thereto can be performed in other sequences that are appropriate. For example, described tasks or events may be performed in an order other than that specifically disclosed, or multiple may be combined in a single block or state. The example tasks or events may be performed in serial, in parallel, or in some other suitable manner. Tasks or events may be added to or removed from the disclosed example aspects. The example systems and components described herein may be configured differently than described. For example, elements may be added to, removed from, or rearranged compared to the disclosed example aspects.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Various components described in this specification may be described as “including” or made of certain materials or compositions of materials. In one aspect, this can mean that the component consists of the particular material(s). In another aspect, this can mean that the component comprises the particular material(s).

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B. and object B touches object C, then objects A and C may still be considered coupled to one another-even if they do not directly physically touch each other. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. The term “about ‘value X”’, or “approximately value X”, as used in the disclosure shall mean within 10 percent of the value X′. For example, a value of about 1 or approximately 1, would mean a value in a range of 0.9-1.1. In one aspect, “about” as used herein may instead mean 5 percent. In the disclosure various ranges in values may be specified, described and/or claimed. It is noted that any time a range is specified, described and/or claimed in the specification and/or claim, it is meant to include the endpoints (at least in one embodiment). In another embodiment, the range may not include the endpoints of the range.

While the above descriptions contain many specific aspects of the invention, these should not be construed as limitations on the scope of the invention, but rather as examples of specific aspects thereof. Accordingly, the scope of the invention should be determined not by the aspects illustrated, but by the appended claims and their equivalents. Moreover, reference throughout this specification to “one aspect,” “an aspect,” or similar language means that a particular feature, structure, or characteristic described in connection with the aspect is included in at least one aspect of the present disclosure. Thus, appearances of the phrases “in one aspect,” “in an aspect.” and similar language throughout this specification may, but do not necessarily, all refer to the same aspect, but mean “one or more but not all aspects” unless expressly specified otherwise.

The terminology used herein is for the purpose of describing particular embodiments only and is not intended to be limiting of the embodiments. As used herein, the singular forms “a.” “an” and “the” are intended to include the plural forms as well (i.e., one or more), unless the context clearly indicates otherwise. An enumerated listing of items does not imply that any or all of the items are mutually exclusive and/or mutually inclusive, unless expressly specified otherwise. It will be further understood that the terms “comprises.” “comprising.” “includes” “including.” “having.” an variations thereof when used herein mean “including but not limited to” unless expressly specified otherwise. That is, these terms may specify the presence of stated features, integers, steps, operations, elements, or components, but do not preclude the presence or addition of one or more other features, integers, steps, operations, elements, components, or groups thereof. Moreover, it is understood that the word “or” has the same meaning as the Boolean operator “OR,” that is, it encompasses the possibilities of “either” and “both” and is not limited to “exclusive or” (“XOR”), unless expressly stated otherwise. It is also understood that the symbol “/” between two adjacent words has the same meaning as “or” unless expressly stated otherwise. Moreover, phrases such as “connected to,” “coupled to” or “in communication with” are not limited to direct connections unless expressly stated otherwise.

Any reference to an element herein using a designation such as “first,” “second,” and so forth does not generally limit the quantity or order of those elements. Rather, these designations may be used herein as a convenient method of distinguishing between two or more elements or instances of an element. Thus, a reference to first and second elements does not mean that only two elements may be used there or that the first element must precede the second element in some manner. Also, unless stated otherwise a set of elements may include one or more elements. In addition, terminology of the form “at least one of a, b, or c” or “a, b, c, or any combination thereof” used in the description or the claims means “a or b or c or any combination of these elements.” For example, this terminology may include a, or b, or c, or a and b, or a and c, or a and b and c, or 2a, or 2b, or 2c, or 2a and b, and so on.

As used herein, the term “determining” encompasses a wide variety of actions. For example, “determining” may include calculating, computing, processing, deriving, investigating, looking up (e.g., looking up in a table, a database or another data structure), ascertaining, and the like. Also, “determining” may include receiving (e.g., receiving information), accessing (e.g., accessing data in a memory), and the like. Also, “determining” may include resolving, selecting, choosing, establishing, and the like.

What is claimed is:

1. A method for verifying functionality of a circuit design, comprising:
performing a test of the circuit design to identify a circuit design error within a first duration of the test;
generating waveform data for a plurality of signals of the circuit design, the waveform data comprising values of the plurality of signals, generated from the test;
generating a stimulus file based on the waveform data, the stimulus file comprising the values of a subset of the plurality of signals and configured to be used to simulate the circuit design to reproduce the circuit design error; and
performing one or more first simulations of the circuit design using the stimulus file to reproduce the circuit design error, each performed within a second duration shorter than the first duration.

2. The method of claim 1:
wherein the circuit design is implemented in a hardware description language (HDL); and
wherein the performing the test comprises simulating the circuit design in a second simulation, wherein each of the one or more first simulations has a shorter duration than a duration of the second simulation.

3. The method of claim 1, wherein the performing the test comprises:
synthesizing the circuit design to be implemented in a field-programmable gate array (FPGA) device;
testing the synthesized circuit design in the FPGA device; and
obtaining the values of the plurality of signals of the circuit design using a logic analyzer provided in the FPGA device.

4. The method of claim 1, wherein the stimulus file comprises a register transfer level (RTL) verification stimulus of the circuit design.

5. The method of claim 1, wherein the performing one or more first simulations of the circuit design using the stimulus file comprises:
determining whether or not the one or more first simulations reproduce the circuit design error using the stimulus file; and
modifying the subset of the plurality of signals included in the stimulus file in response to determining that the one or more first simulations do not reproduce the circuit design error using the stimulus file.

6. The method of claim 5, wherein the modifying the subset of the plurality of signals comprises at least one of:
adding one or more signals to the subset of plurality of signals; or
removing one or more signals from the subset of plurality of signals.

7. The method of claim 1, wherein the generating the waveform data comprises:
generating a value changed dump comprising the values of the plurality of signals.

8. The method of claim 1, wherein the stimulus file comprises:
a first section defining the subset of the plurality of signals; and
a second section defining the values of the subset of the plurality of signals in a temporal order for simulating the circuit design in the one or more first simulations.

9. The method of claim 1, further comprising modifying the circuit design to correct the circuit design error based on the one or more first simulations.

10. A computer system for verifying functionality of a circuit design, comprising:
a processor; and
a memory operatively coupled to the processor, wherein the processor is configured to:
perform a test of the circuit design to identify a circuit design error within a first duration of the test;
generate waveform data for a plurality of signals of the circuit design, the waveform data comprising values of the plurality of signals, generated from the test;
generate a stimulus file based on the waveform data, the stimulus file comprising the values of a subset of the plurality of signals and configured to be used to simulate the circuit design to reproduce the circuit design error; and
perform one or more first simulations of the circuit design using the stimulus file to reproduce the circuit design error, each performed within a second duration shorter than the first duration.

11. The computer system of claim 10:
wherein the circuit design is implemented in a hardware description language (HDL); and
wherein the processor is further configured to simulate the circuit design in a second simulation, wherein each of the one or more first simulations has a shorter duration than a duration of the second simulation.

12. The computer system of claim 10, wherein the processor is further configured to:
synthesize the circuit design to be implemented in a field-programmable gate array (FPGA) device;
test the synthesized circuit design in the FGPA device; and
obtain the values of the plurality of signals of the circuit design using a logic analyzer provided in the FPGA device.

13. The computer system of claim 10, wherein stimulus file comprises a register transfer level (RTL) verification stimulus of the circuit design.

14. The computer system of claim 10, wherein the processor is further configured to:
determine whether or not the one or more first simulations reproduce the circuit design error using the stimulus file; and
modify the subset of the plurality of signals included in the stimulus file in response to determining that the one or more first simulations do not reproduce the circuit design error using the stimulus file.

15. The computer system of claim 14, wherein, to modify the subset of the plurality of signals, the processor is further configured to, at least one of:
add one or more signals to the subset of plurality of signals; or
remove one or more signals from the subset of plurality of signals.

16. The computer system of claim 10, wherein, to generate the waveform data, the processor is further configured to:
generate a value changed dump comprising the values of the plurality of signals.

17. The computer system of claim 10, wherein the stimulus file comprises:
a first section defining the subset of the plurality of signals; and
a second section defining the values of the subset of the plurality of signals in a temporal order for simulating the circuit design in the one or more first simulations.

18. The computer system of claim 10, wherein the processor is further configured to modify the circuit design to correct the circuit design error based on the one or more first simulations.
